(19) United States
(12) Patent Application Publication
(10) Pub. No.: US 2020/0384608 A1
(43) Pub. Date: Dec. 10, 2020

(54) METHOD AND APPARATUS FOR CLEANING A PLASMA PROCESSING APPARATUS

(71) Applicant: Semblant Limited, Riverbank House, 2 Swan Lane (GB)

(72) Inventor: Shailendra Vikram SINGH, Cambridge (GB)

(21) Appl. No.: 16/769,481

(22) PCT Filed: Nov. 30, 2018
(86) PCT No.: PCT/GB2018/053478

§ 371 Date: Jun. 3, 2020

(30) Foreign Application Priority Data
Dec. 5, 2017 (GB) 1720265.6

(51) Int. Cl. B24C 1/08; B24C 1/00; B24C 3/32; B24C 9/00; C23C 16/44

(52) U.S. Cl. CPC B24C 1/086; B24C 1/003; C23C 16/4407; B24C 9/00; B24C 3/32

(57) ABSTRACT

Method of cleaning a first material from a plasma processing apparatus, comprising: subjecting the plasma processing apparatus to a jet of a second material so as to remove the first material from the plasma processing apparatus; mixing the removed first material with a third material configured to dissipate the first material therein.

The present invention relates to cleaning of plasma processing apparatuses. In particular, the invention relates to cleaning plasma processing apparatuses so as to mitigate against the risk of dust explosion resulting from tribocharging of particles generated due to removed coating from the plasma processing apparatus.

Plasma processing may include: plasma deposition, plasma surface activation, plasma etching and plasma cleaning, for example. The type of processing is determined by plasma species generated which is mainly controlled/tuned by the feed gas and/or precursor used. Plasma deposition is a known method for providing conformal coatings to substrates, such as electronics. Plasma surface activation is a known method for changing the surface (e.g. energy) properties of a substrate. Plasma etching is a known method for etching patterns in a substrate, e.g. to fabricate integrated circuits. Plasma cleaning is a known method for removing material from the surface of a substrate.

Plasma processing apparatuses generally comprise a process chamber and a plasma source for providing a plasma within the process chamber. A substrate, e.g. an electrical assembly such as a printed circuit board (PCB), is placed within the chamber, interacts with the plasma and thus is processed. In the case of plasma deposition for example, a coating of material formed from the plasma is deposited on the substrate.

The substrate to be processed is typically supported in the process chamber by a substrate mount. These are usually in the form of aluminium shelves on which the substrates are placed. A number of such substrate mounts may be provided within the process chamber. Other components, such as internal walls of the process chamber, electrodes, etc., are also provided within the process chamber so are exposed to the plasma.

The plasma processing of substrates is performed as a batch process. Obviously, high though-put for the process is desirable. However, it is necessary to periodically pause the process between batches in order to clean components of the plasma processing apparatus. During plasma processing, components within the plasma process chamber (including internal walls, substrate mounts, electrodes, baffle plate, etc.) can become coated. Over a number of batch cycles, a thick deposit of coating builds up. The build-up of coating needs to be removed.

In order to reduce the downtime of the apparatus, cleaning of the plasma process apparatus components needs to be performed as efficiently as possible. Known methods of cleaning include sand blasting, waterjet cleaning and dry-ice blasting. Waterjet cleaning is typically the safest cleaning method. However, the process typically requires a large space, a huge amount of water and a large amount of labour. This method is also very expensive. Dry methods including sand blasting and dry-ice blasting renders the coating into small particles which may become tribocharged. This presents a risk of dust explosion. Some dry-ice blasting apparatuses are provided which reduce the risk of tribocharging and/or a dust explosion by, for example, monitoring the surface charge build-up a component being cleaned or by mixing a the dry-ice jet with steam. However, such apparatuses are typically very large, very expensive and still do not adequately reduce the risk of tribocharging and/or dust explosions.

Combustible dust is defined as a solid material composed of distinct particles or pieces, regardless of size, shape, or chemical composition, which presents a fire or a deflagration hazard when suspended in the air or some other oxidising medium over a range of concentrations. Combustible dusts are often either organic or metal dusts that are finely ground into very small particles, fibres, fines, chips, chunks, flakes or a small mixture of these. Dust particles within an effect of diameter of less than 420 microns should be deemed to meet the criterion of the definition. However, larger particles can still pose a deflagration hazard (for instance, as larger particles are moved, they can abrade each other, creating smaller particles). In addition, particles can stick together due to electrostatic charges accumulated through handling, causing them to become explosive when dispersed.

Five elements are necessary to initiate a dust explosion:
1) Combustible dust (fuel);
2) Ignition source (heat);
3) Oxygen in air (oxidiser);
4) Dispersion of dust particles in sufficient quantity and concentration; and
5) Confinement of the dust cloud.

If particles resulting from the cleaning process become tribocharged, there is a risk that static charge built up will discharge, thus creating a spark. This spark provides an ignition source which could result in a dust explosion.

A dust explosion can cause catastrophic loss of life, injuries, and destruction of buildings. Therefore it is necessary to mitigate against the risk of dust explosion. As mentioned above, known apparatuses either do not adequately mitigate against the risk or are large and expensive, such that it is not feasible to use such apparatuses in many circumstances.

It is an aim of the present invention to at least partially address some of the problems discussed above.

One aspect of the present invention provides a method of cleaning a first material from a plasma processing apparatus, comprising: subjecting the plasma processing apparatus to a jet of a second material so as to remove the first material from the plasma processing apparatus; and mixing the removed first material with a third material configured to dissipate the first material therein.

Another aspect of the invention provides a device for cleaning a plasma processing apparatus, comprising: a first chamber; a first opening, the first chamber through which to receive a first material removed from the plasma processing apparatus by a jet of second material; a second opening in the first chamber through which to receive a third material for mixing with the first material in the first chamber; and a first mixing unit within the first chamber configured to mix the first material and the third material in the first chamber.

The third material acts as a dissipative additive to the first material (e.g. which may include dust particles) which renders the first material inert with respect to causing dust explosions. By mixing the first material removed from the plasma processing apparatus with the third material the risk of tribocharging can be reduced, exposure of the dust to oxygen in air can be reduced and dust particles can be confined. Thus the present invention can reduce or remove three of the five elements required for a dust explosion.

Further features of the invention are described below by way of non-limiting example and with reference to the accompanying drawings in which:

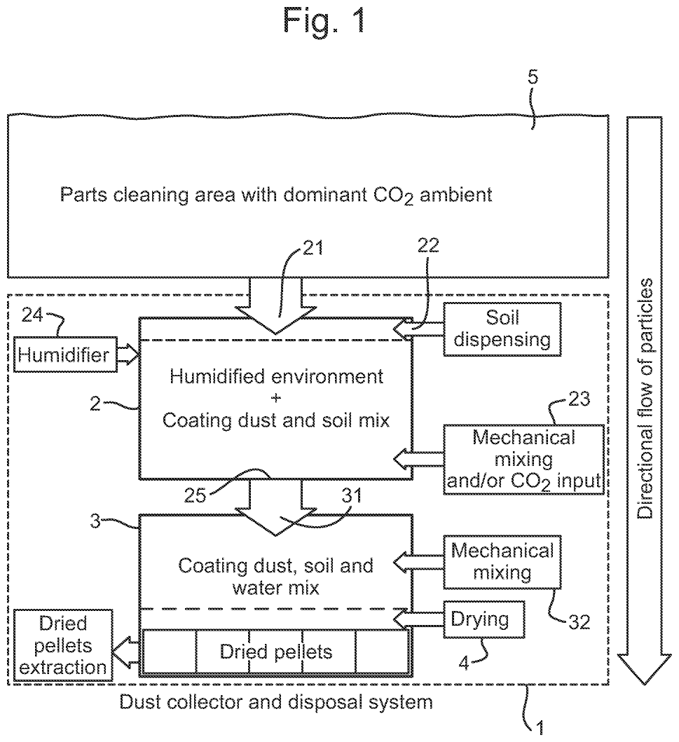

FIG. 1 schematically shows a device for cleaning a plasma processing apparatus in accordance with the invention.

The present invention provides a method of cleaning a first material from a plasma processing apparatus. According to the method, the plasma processing apparatus is subjected to a jet of a second material so as to remove the first material from the plasma processing apparatus.

As described above the first material may be any material resulting from plasma processing, e.g. formed by plasma deposition. Thus, the first material is preferably a coatings formed by plasma deposition. Accordingly, the first material preferably comprises a material obtainable by plasma deposition of one or more precursor compounds. For example, the first material may comprise:
materials (such as those disclosed in WO 2008/102113, WO 2010/020753 and WO 2012/066273, the contents of which are hereby incorporated by reference) obtainable by plasma deposition of one or more halohydrocarbon precursor compounds (particularly fluorohydrocarbons such as hexafluoropropylene);
materials (such as those disclosed in WO 2011/104500, the contents of which are hereby incorporated by reference) obtainable by plasma deposition of one or more aromatic organic precursor compounds such as alkyl-substituted benzene compounds (particularly dimethyl benzenes, for example 1,4-dimethyl benzene, also known as para-xylene);
materials (such as those disclosed in WO 2016/198870, WO 2017/029477 and WO 2017/085482, the contents of which are hereby incorporated by reference) obtainable by plasma deposition of one or more organosilicon compounds (particularly produced using hexamethyldisiloxane); or
mixtures of any of the above materials (such as the multilayer coatings disclosed in WO 2013/132250, WO 2014/155099 and WO 2017/125741 the contents of which are hereby incorporated by reference).

The step of subjecting the plasma processing apparatus to a jet of a second material may include dry-ice blasting or sand blasting for example. Accordingly, the second material may comprise dry-ice or an abrasive material (such as sand).

Dry ice-blasting is a form of carbon dioxide cleaning, where dry ice, the solid form of carbon dioxide, is accelerated in a pressurized fluid stream (typically a gas such as air) and directed at a surface in order to clean it. Dry-ice blasting leaves no chemical residue as dry ice sublimates at room temperature.

Dry-ice blasting involves propelling pellets at extremely high speeds. The actual dry-ice pellets are quite soft, and much less dense than other media used in blast-cleaning (i.e. sand or plastic pellets). Upon impact, the pellet sublimates almost immediately, transferring minimal kinetic energy to the surface on impact and producing minimal abrasion. The sublimation process absorbs a large volume of heat from the surface, producing shear stresses due to thermal shock. This is thought to improve cleaning as the top layer of dirt or contaminant is expected to transfer more heat than the underlying substrate and flake off more easily. The rapid change in state from solid to gas also causes microscopic shock waves, which are also thought to assist in removing the contaminant. Dry-ice blasting is nonabrasive, nonconductive and non-flammable. Dry-ice blasting generates no additional waste or secondary contamination unlike media and water blasting.

Abrasive blasting is the operation of forcibly propelling a stream of abrasive material against a surface under high pressure. A pressurized fluid, typically compressed air, or a centrifugal wheel is used to propel the blasting material (often called the media). There are several variants of the process, using various media; some are highly abrasive, whereas others are milder. For the present application, namely cleaning plasma processing apparatus, sand blasting (with sand) is often preferred due to its simplicity and reliability. Variants include shot blasting (with metal shot), glass bead blasting (with glass beads), soda-blasting (with baking soda) and media blasting with ground-up plastic stock.

The removed first material is then mixed with a third material configured to dissipate the first material therein. The third material acts as a dissipative additive to the first material which renders the first material inert with respect to causing dust explosions. By mixing the first material removed from the plasma processing apparatus with the third material the risk of tribocharging can be reduced, exposure of the dust to oxygen in air can be reduced and dust particles can be confined.

FIG. 1 schematically shows a system 1 for cleaning a plasma processing apparatus. As shown in FIG. 1, the system 1 comprises a first chamber 2. The first chamber 2 receives the first material removed from the plasma processing apparatus, e.g. by a jet of the second material. For this purpose, the system 1 comprises a first opening 21 in the first chamber 2 through which to receive the first material. The system 1 further comprises a second opening 22 in the first chamber 2 through which to receive the third material for mixing with the first material in the first chamber 2. A first mixing unit 23 is provided within the first chamber 2 and configured to mix the first material and the third material in the first chamber 2.

The mixing unit 23 may comprise a mechanical paddle that moves, e.g. rotates to mix the first and third materials together. Alternatively, mixing may be performed by a flow of gas, such as carbon dioxide gas.

The step of removing the first material may be performed in a low oxygen environment and/or a high CO₂ environment. Accordingly, the system 1 may comprise an additional chamber 5, shown in FIG. 1, in which the plasma processing apparatus is subjected to the jet of the second material. This chamber 5 may be configured to provide an atmosphere comprising a higher CO₂ content than air. This reduces the amount risk of explosion by reducing the relative amount of oxygen in the chamber 5.

Preferably, the third material comprises soil. Soil has favourable properties for the present application. For example, soil is suitably mixable, such that it can combine well with solid dust particles. Soil has good moisture retention, thus protecting against combustion. Soil has suitable resistivity such that electric charge can be effectively dissipated. Further, soil is an inexpensive and readily available material.

Soil typically comprises: minerals, organic matter, water and air. A typical soil consists of approximately 45 wt % mineral, 5 wt % organic matter, 20-30 wt % water, and 20-30 wt % air.

The mineral material from which a soil forms is called parent material. Typical soil parent mineral materials are: Quartz (SiO₂); Calcite (CaCO₃); Feldspar (KAlSi₃O₈); and Mica (biotite—K(Mg,Fe)₃AlSi₃O₁₀(OH)₂). Any number of these materials may be present in the soil in varying quantities. Other mineral materials may also be present such as metal oxides, including aluminium oxides and iron oxides.

The composition of the soil used in the present invention may be selected based on properties of the first material. The properties may include a dust explosion class. Dust explosion class is defined in US directive CPL 03-00-008, Combustible Dust National Emphasis Program. Dust explosion class is based on Kst. Kst is the Deflagration Index for dusts, and the Kst test results provide an indication of the severity of a dust explosion. The larger the value for Kst, the more severe is the explosion (See Table 1). Kst is essentially the maximum rate of pressure rise generated when dust is tested in a confined enclosure. Kst provides the best “single number” estimate of the anticipated behaviour of a dust deflagration.

TABLE 1

| Dust explosion | | |
|---|---|---|
| class | Kst (bar.m/s) | Characteristic |
| St 0 | 0 | No explosion |
| St 1 | >0 and <=200 | Weak explosion |
| St 2 | >200 and <=300 | Strong explosion |
| St 3 | >300 | Very strong |
| | | explosion |

Approximately 300 grams of “as received” sample material are needed for the Kst test. In this test, dust is suspended in a 20-liter explosibility testing chamber and is ignited using a chemical igniter. The 20-liter explosibility testing chamber determines maximum pressure and rate of pressure rise if the sample explodes. These parameters are used to determine the maximum normalized rate of pressure rise (Kst).

Kst is calculated with the following formula: Kst=(dP/dt)max V^{1/3}. (dP/dt) max=the maximum rate of pressure rise; V=the volume of the testing chamber. The test involves the following steps:

a) The sample dust is suspended in a 20-liter explosion chamber. (Use 2500 J Sobbe igniters if using the Bureau of Mines test chamber.)

b) The dust is tested “as received” (except drying, if the moisture content is greater than 5 wt %).

c) Test at three to five dust concentrations, from 500 g/m³ to about 2500 g/m³, plotting the found maximum normalized dP/dt values versus dust concentration, and reporting the highest value from the plateau of the plot.

Depending on the explosibilty of the first material, the chosen soil composition may have a mineral content (e.g. including SiO₂, mica and other oxides like Al₂O₃) of between 20 wt % and 50 wt %. For a material having low explosibilty, e.g., for st0 and st1 materials, the soil may have a mineral concentration of 30 wt % to 50 wt %. For an st2 material, a mineral content of 20 wt % to 30 wt % is preferred. For st3 materials mineral content of less than 20 wt % is preferred, for example 10 to 20 wt %.

The soil preferably comprises no more than 25 wt % water.

The ratio of the first material to third material (e.g. soil) may vary from 1:1 for st0 materials; 1:2 or above for st1 materials; 1:4 or above for st2 material. For st3 materials ratios of between 1:6 and 1:8 or even higher may be used depending on the explosibilty.

Mixing is preferably performed in a humidified environment. This reduces the risk of tribocharging. Accordingly, as shown in FIG. 1, the system 1 may comprise a humidifier 24 configured to humidify the first chamber 2. The humidifier 24 allows the moisture level within the mixture to be controlled. Preferably the humidity in the first chamber 2 is controlled in such a way that the mixture remains dry enough such that it does not stick to the walls of the first chamber 2.

Preferably, the mixed first and third materials are additionally mixed with water. This helps the soil mixture to cake, i.e. harden when dried.

Accordingly, as shown in FIG. 1, the system 1 may comprise a third opening 25 in the first chamber 2 through which to eject mixed first and third materials from the first chamber 2; a second chamber 3; a fourth opening 31 in the second chamber through which receive the mixed first and third materials ejected from the first chamber 2; and a second mixing unit 32 within the second chamber 3 configured to mix the first material and the third material with water in the second chamber 3.

It is preferable convert the mixture resulting from the above process into a form more suitable for transport and/or disposal. For example, the mixture may be converted into pellets. Therefore, the mixed first and third materials may be dried. Accordingly, the system 1 may comprise a drying unit 4 configured to dry the mixed first and third materials. For example, the drying unit may comprise an oven or heater (preferably electrical) or a dehydrator. Alternatively, the drying unit 4 may be an open container that allows the mixture to dry naturally. From the dried mixture, solid pellets may be formed, e.g. by breaking the dried mixture into pieces. Alternatively, prior to drying, the mixture may be distributed into multiple small compartments within the drying unit 4, such that the mixture in each compartment dries to form a pellet.

1. Method of cleaning a first material from a plasma processing apparatus, comprising:
subjecting the plasma processing apparatus to a jet of a second material so as to remove the first material from the plasma processing apparatus;
mixing the removed first material with a third material configured to dissipate the first material therein.

2. The method of claim 1, wherein the second material comprises at least one of: sand and dry ice.

3. The method of claim 1, wherein the third material comprises soil.

4. The method of claim 3, wherein the soil comprises minerals, organic material, water and air.

5. The method of claim 1, wherein the mixing is performed in a humidified environment.

6. The method of claim 1, wherein the mixed first and third materials are additionally mixed with water.

7. The method of claim 1, further comprising drying the mixed first and third materials.

8. The method of claim 1, further comprising forming solid pellets from the mixed first and third materials.

9. The method of claim 1, wherein the first material is obtainable by plasma deposition.

10. The method of claim 9, wherein the first material is obtainable by plasma deposition of one or more precursor compounds selected from fluorohydrocarbon compounds, alkyl-substituted benzene compounds and organosilicon compounds.

11. The method of claim 1, wherein the first material is flammable.

12. A device for cleaning a plasma processing apparatus, comprising:
a first chamber;
a first opening in the first chamber through which to receive a first material removed from the plasma processing apparatus by a jet of a second material;
a second opening in the first chamber through which to receive a third material for mixing with the first material in the first chamber;
a first mixing unit within the first chamber configured to mix the first material and the third material in the first chamber.

13. The device of claim 12, further comprising:
a humidifier configured to humidify the first chamber.

14. The device of claim 12, further comprising:
a third opening in the first chamber through which to eject mixed first and third materials from the first chamber;
a second chamber;
a fourth opening in the second chamber through which receive the mixed first and third materials ejected from the first chamber;
a second mixing unit within the second chamber configured to mix the first material and the third material in the second chamber;
a drying unit configured to dry the mixed first and third materials.
